(19) United States
(12) Patent Application Publication
(10) Pub. No.: US 2012/0017826 A1
(43) Pub. Date: Jan. 26, 2012

(54) METHOD FOR MANUFACTURING SILICON CARBIDE SUBSTRATE

(75) Inventors: Taro Nishiguchi, Hyogo (JP); Makoto Sasaki, Hyogo (JP); Shin Harada, Osaka (JP); Kyoko Okita, Hyogo (JP); Hiroki Inoue, Hyogo (JP); Yasuo Namikawa, Osaka (JP)

(73) Assignee: Sumitomo Electric Industries, Ltd., Osaka-shi (JP)

(21) Appl. No.: 13/258,126

(22) PCT Filed: Sep. 28, 2010
(86) PCT No.: PCT/JP2010/066829

§ 371 Date: Sep. 21, 2011

(30) Foreign Application Priority Data
Mar. 2, 2010 (JP) 2010 045623

(51) Int. Cl. C30B 23/06

(52) U.S. Cl. 117/106

(57) ABSTRACT

A supporting portion (30c) made of silicon carbide has irregularities at at least a portion of a main surface (FO). The supporting portion (30c) and at least one single crystal substrate (11) made of silicon carbide are stacked such that the backside surface (B1) of each at least one single crystal substrate (11) and the main surface (FO) of the supporting portion (30c) having irregularities formed contact each other. In order to connect the backside surface (B1) of each at least one single crystal substrate (11) to the supporting portion (30c), the supporting portion (30c) and at least one single crystal substrate (11) are heated such that the temperature of the supporting portion (30c) exceeds the sublimation temperature of silicon carbide, and the temperature of each at least one single crystal substrate (11) is below the temperature of the supporting portion (30c).

### TECHNICAL FIELD

The present invention relates to a method for manufacturing a silicon carbide substrate.

### BACKGROUND ART

An SiC (silicon carbide) substrate has recently increasingly been adopted as a semiconductor substrate used for manufacturing a semiconductor device. SiC has a band gap wider than Si (silicon) that has been used more commonly. Therefore, a semiconductor device including an SiC substrate is advantageous in a high breakdown voltage, a low ON resistance and less lowering in characteristics in an environment at a high temperature.

In order to efficiently manufacture a semiconductor device, a substrate is required to have a size not smaller than a certain size. According to U.S. Pat. No. 7,314,520 (Patent Literature 1), an SiC substrate not smaller than 76 mm (3 inches) can be manufactured.

### CITATION LIST

### Patent Literature

PTL 1: U.S. Pat. No. 7,314,520

### SUMMARY OF INVENTION

### Technical Problem

Industrially, the size of an SiC single crystal substrate is still limited to approximately 100 mm (4 inches). Accordingly, semiconductor devices cannot be efficiently manufactured using large single crystal substrates, disadvantageously. This disadvantage becomes particularly serious in the case of using the property of a plane other than the (0001) plane in SiC of hexagonal system. Hereinafter, this will be described.

An SiC single crystal substrate small in defect is usually manufactured by slicing an SiC ingot obtained by growth in the (0001) plane, which is less likely to cause stacking fault. Hence, a single crystal substrate having a plane orientation other than the (0001) plane is obtained by slicing the ingot not in parallel with its grown surface. This makes it difficult to sufficiently ensure the size of the single crystal substrate, or many portions in the ingot cannot be used effectively. For this reason, it is particularly difficult to effectively manufacture a semiconductor device that employs a plane other than the (0001) plane of SiC.

Instead of increasing the size of such an SiC single crystal substrate with difficulty, it is considered to use a silicon carbide substrate having a supporting portion and a plurality of small single crystal substrates connected thereon. The size of the silicon carbide substrate can be made larger by increasing the number of single crystal substrates as required. However, in the case where such a supporting portion and single crystal substrate are connected, the strength of the connection may be insufficient.

The present invention was made in view of the above-described problem, and an object of the present invention is to provide a method for manufacturing a silicon carbide substrate that can have the connecting strength between a single crystal substrate and a supporting portion increased.

### Solution to Problem

A method for manufacturing a silicon carbide substrate of the present invention includes the following steps.

At least one single crystal substrate, each having a backside surface and made of silicon carbide, is prepared. A supporting portion having a main surface and made of silicon carbide is prepared. At least a portion of the main surface of the supporting portion has irregularities. The supporting portion and at least one single crystal substrate are stacked such that a backside surface of each at least one single crystal substrate and the main surface of the supporting portion having irregularities formed contact each other. In order to connect the backside surface of each at least one single crystal substrate to the connecting portion, the supporting portion and at least one single crystal substrate are heated such that the temperature of the supporting portion exceeds the sublimation temperature of silicon carbide, and the temperature of each at least one single crystal substrate is below the temperature of the supporting portion.

Since a cavity is ensured between the supporting portion and single crystal substrate by the irregularities of the supporting portion in the present invention, the temperature of the single crystal substrate can be set reliably lower that the temperature of the supporting portion. This allows the mass transfer from the supporting portion to the single crystal substrate associated with the sublimation recrystallization reaction to occur more reliably. Therefore, the connecting strength between the single crystal substrate and supporting portion can be increased.

Preferably, the step of preparing a supporting portion includes the steps of forming a main surface, and forming irregularities on the main surface. Therefore, formation of a main surface and the formation of irregularities can be carried out independently.

Preferably, the step of forming irregularities includes the step of grinding the surface so as to roughen the main surface. Preferably, the step of grinding the main surface includes the step of grinding the main surface in one linear direction.

Preferably, the step of forming irregularities includes the step of applying a predetermined surface feature to the main surface. Preferably, the surface feature includes a plurality of recesses extending on the main surface along a first direction. Preferably, the surface feature includes a recess extending on the main surface along a second direction crossing the first direction. Preferably, the surface feature includes a recess extending on the main surface in the circumferential direction.

In the step of preparing a supporting portion, a surface layer having a distortion in the crystal structure may be formed on the main surface. Preferably, before the step of stacking a supporting portion and at least one single crystal substrate, at least a portion of the surface layer is removed chemically.

Preferably, at least one single crystal substrate has a hexagonal crystal structure, and an off angle greater than or equal to 50° and less than or equal to 65° relative to the {0001} plane.

Preferably, the irregularities have a random direction. Accordingly, the anisotropy of the irregularities becomes smaller.

Preferably, the step of preparing a supporting portion includes the step of forming the main surface by slicing. Irregularities are formed by the slicing. Accordingly, the steps of manufacturing a silicon carbide substrate can be simplified since it is not necessary to carry out an independent step just for forming irregularities.

Preferably, the back surface of each at least one single crystal substrate is formed by slicing.

Preferably, a heating step is carried out in an atmosphere having pressure higher than 10⁻¹ Pa and lower than 10⁴ Pa.

### Advantageous Effects of Invention

As from the description set forth above, the connecting strength between the single crystal substrate and supporting portion can be increased according to the method for manufacturing a silicon carbide substrate of the present invention.

### BRIEF DESCRIPTION OF DRAWINGS

FIG. 1 is a plan view schematically representing a configuration of a silicon carbide substrate in a first embodiment of the present invention.

FIG. 2 is a schematic sectional view taken along line II-II in FIG. 1.

FIG. 3 is a sectional view schematically showing a first step in a method for manufacturing a silicon carbide substrate in the first embodiment of the present invention.

FIG. 4 is a partial top view schematically showing a second step in the method for manufacturing a silicon carbide substrate in the first embodiment of the present invention.

FIG. 5 is a schematic sectional view taken along line V-V in FIG. 4.

FIG. 6 is a sectional view schematically showing a third step in the method for manufacturing a silicon carbide substrate in the first embodiment of the present invention.

FIG. 7 is a sectional view schematically showing a fourth step in the method for manufacturing a silicon carbide substrate in the first embodiment of the present invention.

FIG. 8 is a partial enlarged view of FIG. 7.

FIG. 9 is a partial sectional view schematically showing a mass transfer direction by sublimation in a fifth step of the method for manufacturing a silicon carbide substrate in the first embodiment of the present invention.

FIG. 10 is a partial sectional view schematically showing a cavity transfer direction by sublimation in the step corresponding to FIG. 9.

FIG. 11 is a partial sectional view schematically showing a void transfer direction by sublimation in a sixth step of the method for manufacturing a silicon carbide substrate in the first embodiment of the present invention.

FIG. 12 is a sectional view schematically representing one step in a method for manufacturing a silicon carbide substrate in a comparative example.

FIG. 13 is a plan view schematically representing a configuration of a silicon carbide substrate in a second embodiment of the present invention.

FIG. 14 is a plan view schematically showing one step in a method for manufacturing a silicon carbide substrate in the second embodiment of the present invention.

FIG. 15 is a schematic sectional view taken along line XV-XV in FIG. 14.

FIG. 16 is a sectional view schematically showing one step in a method for manufacturing a silicon carbide substrate according to a first modification in the second embodiment of the present invention.

FIG. 17 is a sectional view schematically showing one step in a method for manufacturing a silicon carbide substrate according to a second modification in the second embodiment of the present invention.

FIG. 18 is a top view schematically showing one step in a method for manufacturing a silicon carbide substrate according to a third modification in the second embodiment of the present invention.

FIG. 19 is a plan view schematically showing one step in a method for manufacturing a silicon carbide substrate according to a fourth modification in the second embodiment of the present invention.

FIG. 20 is a perspective view schematically showing one step in a method for manufacturing a silicon carbide substrate in a third embodiment of the present invention.

FIG. 21 is a partial sectional view schematically representing a configuration of a semiconductor device in a fifth embodiment of the present invention.

FIG. 22 is a flowchart schematically representing a method for manufacturing a semiconductor device in the fifth embodiment of the present invention.

FIG. 23 is a partial sectional view schematically showing a first step in the method for manufacturing a semiconductor device in the fifth embodiment of the present invention.

FIG. 24 is a partial sectional view schematically showing a second step in the method for manufacturing a semiconductor device in the fifth embodiment of the present invention.

FIG. 25 is a partial sectional view schematically showing a third step in the method for manufacturing a semiconductor device in the fifth embodiment of the present invention.

FIG. 26 is a partial sectional view schematically showing a fourth step in the method for manufacturing a semiconductor device in the fifth embodiment of the present invention.

### DESCRIPTION OF EMBODIMENTS

Embodiments of the present invention will be described hereinafter based on the drawings.

### First Embodiment

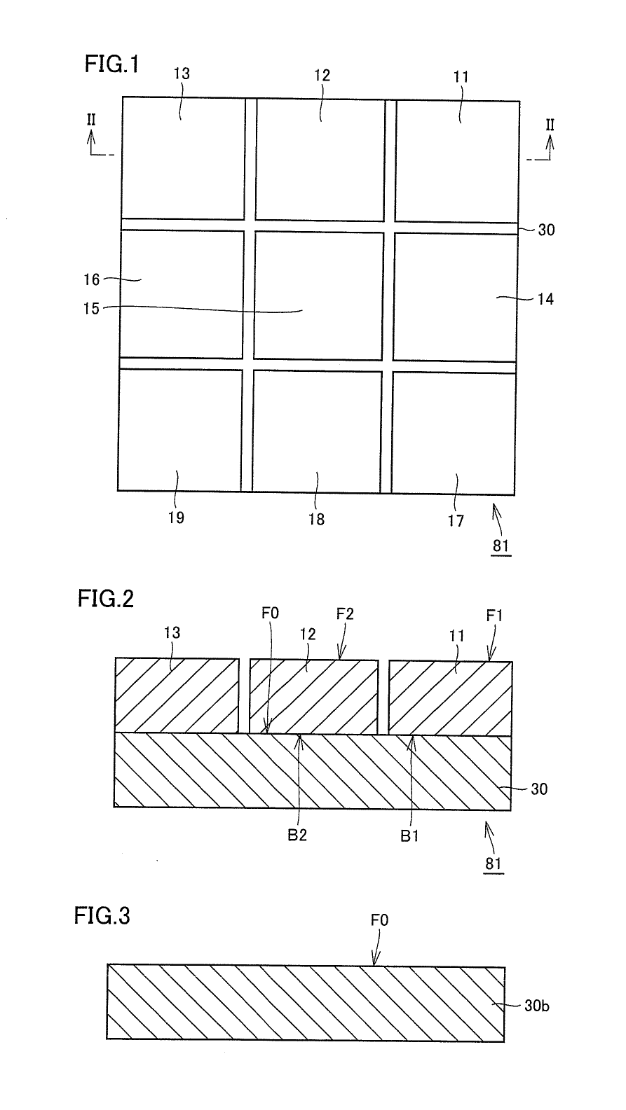

Referring to FIGS. 1 and 2, a silicon carbide substrate 81 of the present embodiment is made of SiC. Silicon carbide substrate 81 preferably has a thickness of at least a certain degree (the dimension in the vertical direction in FIG. 2), preferably greater than or equal to 300 μm, for example, for convenience in handling in the steps of manufacturing a semiconductor device using such a substrate. The shape of the silicon carbide substrate in plane is a square having one side of 60 mm, for example. Silicon carbide substrate 81 includes a supporting portion 30, and single crystal substrates 11-19. Supporting portion 30 is a layer made of SiC, having a main surface FO. Single crystal substrates 11-19 are made of SiC, arranged in a matrix, as shown in FIG. 1. The back surface of each of single crystal substrates 11-19 and main surface FO of supporting portion 30 are connected to each other. Single crystal substrate 11 has a front side surface F1 and a backside surface B1 opposite to each other. Single crystal substrate 12 has a front side surface F2 and a backside surface B2 opposite to each other. Each of backside surfaces B1 and B2 is connected to main surface FO. The remaining single crystal substrates 13-19 have a similar configuration.

Each of single crystal substrates 11-19 preferably has a hexagonal crystal structure, and more preferably an off angle greater than or equal to 50° and less than or equal to 65°, relative to the {0001} plane, and further preferably a plane orientation of {03-38}. As the plane orientation, {0001}, {11-20} or {1-100} can also be employed. Further, a plane offset by several degrees from each of the aforementioned plane orientation may also be used. Regarding various polytypes of the hexagonal system, the 4H polytype is particularly preferable. For example, each of single crystal substrates 11-19 has a plane configuration of 20×20 mm, a thickness of 300 μm, the 4H polytype, the plane orientation of {03-38}, an n type impurity concentration of 1×10¹⁹ cm⁻³, a micropipe density of 0.2 cm⁻², and a stacking defect density less than 1 cm⁻¹.

Supporting portion 30 may have the crystal structure of single crystal, polycrystal, and amorphous. Preferably, supporting portion 30 has a crystal structure similar to that of single crystal substrates 11-19. In general, the amount of defect in supporting portion 30 may be greater as compared to that of single crystal substrates 11-19. Therefore, the impurity concentration of supporting portion 30 can be readily increased as compared to the impurity concentration of single crystal substrates 11-19. For example, supporting portion 30 has a plane shape of 60×60 mm, a thickness of 300 μm, the 4H polytype, a plane orientation of {03-38}, an n impurity concentration of 1×10²⁰ cm⁻³, a micropipe density of 1×10⁴ cm⁻², and a stacked defect density of 1×10⁵ cm⁻¹.

Preferably, the shortest distance between single crystal substrates 11-19 (for example, the horizontal distance between single crystal substrates 11 and 12 in FIG. 2) is set less than or equal to 5 mm, preferably less than or equal to 1 mm, more preferably less than or equal to 100 μm, and further preferably less than or equal to 10 μm.

A method for manufacturing silicon carbide substrate 81 will be described hereinafter. Although only single crystal substrates 11 and 12 among single crystal substrates 11-19 may be mentioned for the sake of simplification in the following description, single crystal substrates 11-19 follow the description of single crystal substrates 11 and 12.

Referring to FIG. 3, a substrate 30b made of SiC, and having a main surface FO is prepared. This preparation corresponds to obtaining an SiC substrate by slicing a mass made of SiC, in other words, forming a main surface FO at the mass. The crystal structure of substrate 30b may be any of a single crystal structure, polycrystal structure, and amorphous structure. The material of substrate 30b may be deposited by crystal growth, or by sintering. Substrate 30b has a square main surface FO of approximately 60 mm×60 mm, and a thickness of 300 μm.

Then, irregularities are formed at main surface FO. The irregularities can be formed by the step of grinding main surface FO so as to roughen main surface FO to a desired degree. This step can be carried out by rubbing main surface FO. This rubbing can be carried out by relative motion between a pad impregnated with slurry including abrasive grains and main surface FO, pressed against each other under a predetermined pressure. The size of the abrasive grains can be determined depending upon the degree of irregularities to be formed, and is 9 μm, for example. The substance of the crystal grains preferably has a hardness equal to or greater than that of SiC, and is diamond, for example. The aforementioned pressure is, for example, 0.1 to 0.2 kg/cm². The aforementioned relative motion is a reciprocating movement of 1000 times across a length of approximately 30 cm along one linear direction.

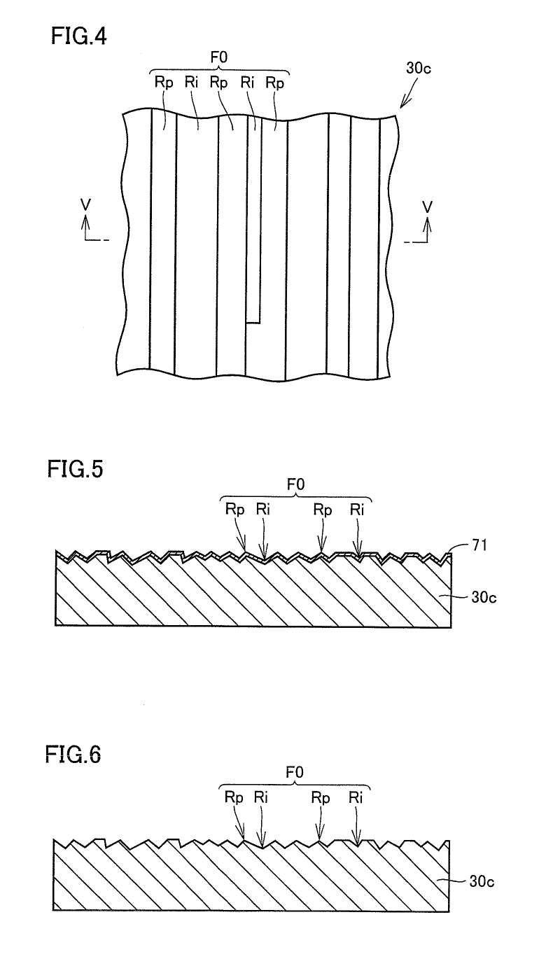

Referring mainly to FIGS. 4 and 5, a supporting portion 30c having a main surface FO with irregularities formed is prepared by the aforementioned formation of irregularities. The irregularities correspond to the surface roughness of Ra=20 μm, for example. The irregularities include a recess Ri and a projection Rp. Recess Ri is the region more cut away than projection Rp at main surface FO. The difference in height between projection Rp and recess Ri is 5 μm, for example.

A surface layer 71 having a distortion in the crystal structure may be formed on main surface FO due to the step of forming irregularities. Preferably by chemically removing at least a portion of surface layer 71, the amount of surface layer 71 is reduced, as shown in FIG. 6. Specific methods thereof include, for example, etching, or formation and removal of an oxide film. Specifically, the etching method includes wet etching, gas etching, or RIE (Reactive Ion Etching).

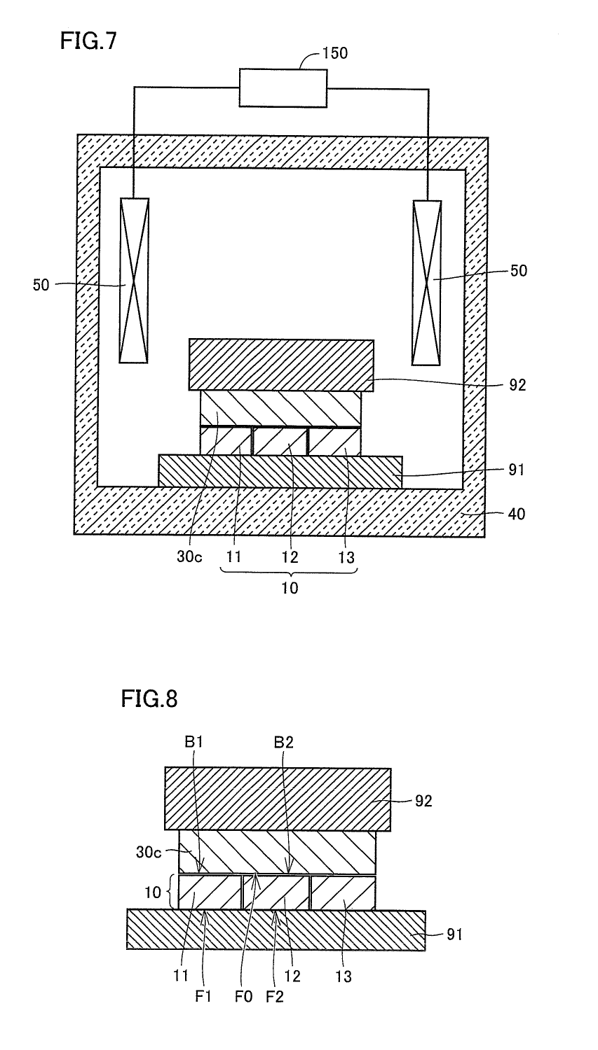

Referring to FIGS. 7 and 8, single crystal substrates such as single crystal substrates 11 and 12 (also referred to as “single crystal substrate group 10”, generically), and a heating device are prepared. The backside surface of each single crystal substrate may be a surface formed by slicing, i.e. a surface not rubbed after formation by slicing. In this case, appropriate irregularities are provided on the backside surface. The heating device includes first and second heat bodies 91 and 92, a heat-insulating container 40, a heater 50, and a heater power source 150. Heat-insulating container 40 is made of a material of high heat resistance. Heater 50 is, for example, an electrical resistance heater. First and second heat bodies 91 and 92 are capable of heating supporting portion 30c and single crystal substrate group 10 by reradiation of the heat obtained by absorbing the emitted heat from heater 50. First and second heat bodies 91 and 92 are made of graphite, for example, having low porosity.

First heat body 91, single crystal substrate group 10, supporting portion 30c, and second heat body 92 are arranged so as to be stacked in the cited order. Specifically, single crystal substrates 11-19 (FIG. 1) are arranged in a matrix on first heat body 91. Then, single crystal substrate group 10 and supporting portion 30c are stacked such that main surface FO of supporting portion 30c forms contact with the backside surface of each single crystal substrate in single crystal substrate group 10. Second heat body 92 is placed on supporting portion 30c. The stacked first heat body 91, single crystal substrate group 10, supporting portion 30c and second heat body 92 are accommodated in heat-insulating container 40 in which heater 50 is provided.

The atmosphere in heat-insulating container 40 is obtained by reducing the atmospheric pressure. The pressure of the atmosphere is preferably set higher than 10⁻¹ Pa and lower than 10⁴ Pa.

The aforementioned atmosphere may be inert gas atmosphere. For inert gas, noble gas such as He or Ar, nitrogen gas, or mixed gas of the noble gas and nitrogen gas can be used, for example. The pressure in heat-insulating container 40 is preferably less than or equal to 50 kPa, more preferably less than or equal to 10 kPa.

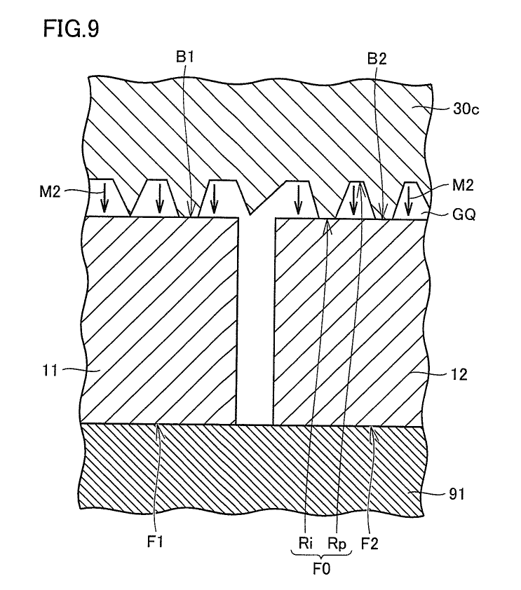

Referring to FIG. 9, supporting portion 30c is just placed on each of single crystal substrates 11 and 12, and not yet connected at this point of time. Between each of backside surfaces B1 and B2 and supporting portion 30c is provided a small cavity GQ due to the presence of irregularities formed at main surface FO of supporting portion 30c. By heater 50, single crystal substrate group 10 including single crystal substrates 11 and 12, and supporting portion 30c are heated by heater 50 through first and second heat bodies 91, 92. This heating is carried out such that the temperature of supporting portion 30c exceeds the sublimation temperature of SiC, and each temperature in single crystal substrate group 10 is less than the temperature of supporting portion 30. In other words, a temperature gradient is produced such that the temperature becomes lower in the downward direction in FIG. 9. This temperature gradient is preferably greater than or equal to 1° C./cm and less than or equal to 200° C./cm, more preferably greater than or equal to 10° C./cm and less than or equal to 50° C./cm, between each of single crystal substrates 11 and 12 and supporting portion 30. By such a temperature gradient in the thickness direction (vertical direction in FIG. 9), the temperature of single crystal substrates 11 and 12 becomes lower than the temperature of supporting portion 30c in the region where each of single crystal substrates 11 and 12 is separated from supporting portion 30c by cavity GQ. As a result, the sublimation reaction of SiC into cavity GQ occurs more readily from supporting portion 30c as compared to single crystal substrates 11 and 12, and the recrystallization reaction by the supply of the SiC material from cavity GQ occurs more readily on single crystal substrates 11 and 12 as compared to supporting portion 30c. As a result, mass transfer caused by sublimation occurs in cavity GQ, as indicated by arrow M2 in the drawing.

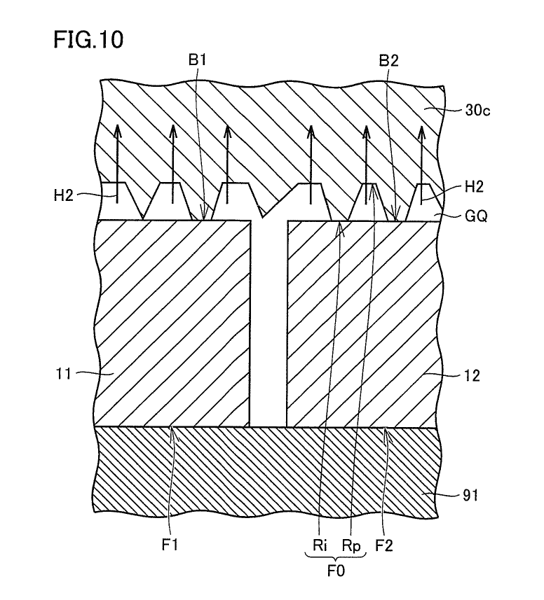

The mass transfer indicated by arrow M2 in FIG. 9 conversely corresponds to the transfer indicated by arrow 1-12 (FIG. 10) in the space where cavity GQ is present. In accordance with this transfer, supporting portion 30c is connected to each of single crystal substrates 11 and 12. Thus, in accordance with the transfer, supporting portion 30c is converted from the initially prepared state to that reformed by the re-growth on single crystal substrates 11 and 12. This conversion gradually progresses from the region close to single crystal substrates 11 and 12.

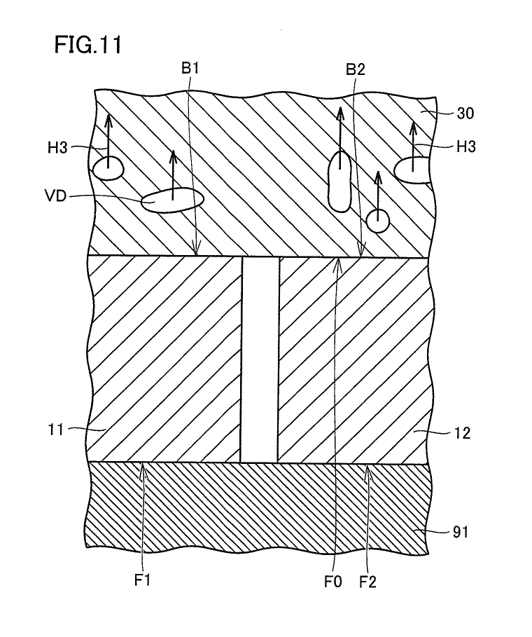

By the aforementioned regrowth, supporting portion 30c changes to a supporting portion 30 (FIG. 11) including a region having a crystal structure corresponding to the crystal structure of single crystal substrates 11 and 12. The space corresponding to cavity GQ (FIG. 10) constitutes void VD (FIG. 11) in supporting portion 30. According to the continuation of heating, void VD moves away from main surface FO, as indicated by arrow H3 (FIG. 11). Accordingly, the connecting strength is further increased. Further, the region in supporting portion 30 where the crystal structure corresponds to that of single crystal substrates 11 and 12 further expands. Thus, a silicon carbide substrate 81 (FIG. 2) is obtained.

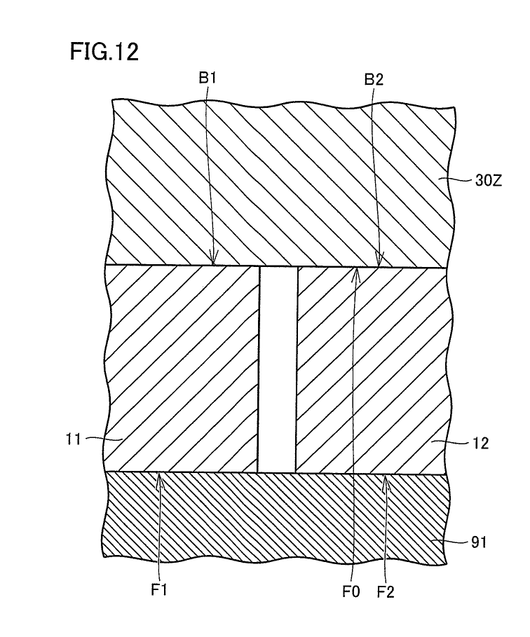

A method for manufacturing a silicon carbide substrate of a comparative example (FIG. 12) will be described hereinafter. In the present comparative example, a supporting portion 30Z without irregularities formed on main surface FO is prepared, instead of the above-described supporting portion 30c. Therefore, when supporting portion 30Z is placed on each of single crystal substrates 11 and 12, no cavity GQ (FIG. 9) is substantially provided, differing from the present embodiment. As a result, each of backside surfaces B1 and B2 of single crystal substrates 11 and 12 will be substantially in close contact with main surface FO of supporting portion 30Z. It is therefore difficult to set the temperature at each of backside surfaces B1 and B2 sufficiently lower than the temperature at main surface FO. This leads to difficulty in causing mass transfer from main surface FO towards each of backside surfaces B1 and B2 (for example, the mass transfer indicated by arrow M2 in FIG. 9). This may reduce the connecting strength between the supporting portion and single crystal substrate effected by the aforementioned mass transfer.

In contrast, the present embodiment readily allows temperature difference between supporting portion 30c and each of single crystal substrates 11 and 12 by virtue of cavity GQ therebetween due to supporting portion 30c (FIG. 9) having irregularities. The temperature of single crystal substrates 11 and 12 can he reliably set lower than the temperature of supporting portion 30c. Specifically, the temperature at backside surfaces B1 and B2 can be reliably set lower more than the temperature at main surface FO. Accordingly, generation of mass transfer from supporting portion 30c towards single crystal substrates 11 and 12 (FIG. 9: arrow M2) in association with the sublimation recrystallization reaction is further ensured, allowing increase of the connecting strength between each of single crystal substrates 11 and 12 and supporting portion 30c.

When the backside surfaces of each single crystal substrate is formed by slicing, appropriate irregularities are provided on the backside surface, which also allows the formation of a cavity, likewise with cavity GQ. Therefore, the functional effect set forth above can be enhanced.

According to the present embodiment, surface layer 71 (FIG. 5) is removed chemically. This chemical removal will not newly cause distortion in the crystal structure at backside surfaces B1 and B2, differing from mechanical removal. Thus, at least a portion of surface layer 71 can be removed more reliably. This allows the connecting strength between each of backside surfaces B1, B2 and main surface FO to be increased. Further, increase in the electrical resistance in the thickness direction (vertical direction in FIG. 2) caused by the presence of surface layer 71 at silicon carbide substrate 81 (FIG. 2) can be suppressed.

Preferably, each of single crystal substrates 11-19 has a crystal structure of the 4H polytype. Thus, a silicon carbide substrate 81 suitable for manufacturing a semiconductor directed to electric power use can be obtained.

Preferably, in order to prevent silicon carbide substrate 81 from cracking, the difference between the thermal expansion coefficient of supporting portion 30 and the thermal expansion coefficient of single crystal substrates 11-19 in silicon carbide substrate 81 is made as small as possible. Accordingly, occurrence of a warpage at silicon carbide substrate 81 can be suppressed. To this end, the crystal structure of supporting portion 30 is to be identical to that of single crystal substrates 11-19. Specifically, the crystal structure of supporting portion 30 is made to match that of single crystal substrates 11-19 by sufficient mass transfer (FIG. 9: arrow M2) through sublimation and recrystallization.

Preferably, the electrical resistivity of supporting portion 30c (FIG. 6) is less than 50 mΩ·cm, more preferably less than 10 mΩ·cm.

The impurity concentration of supporting portion 30 of silicon carbide substrate 81 is greater than or equal to 5×10¹⁸ cm⁻³, more preferably greater than or equal to 1×10²⁰ cm⁻³. By manufacturing a vertical type semiconductor device conducting a current flow in the vertical direction such as a vertical MOSFET (Metal Oxide Semiconductor Field Effect Transistor) employing such silicon carbide substrate 81, the on resistance of the vertical type semiconductor device can be reduced.

Preferably, the average value of the electrical resistivity of silicon carbide substrate 81 is preferably less than or equal to 5 mΩ·cm, more preferably less than or equal to 1 mΩ·cm.

Preferably, surface F1 (FIG. 2) has an off angle greater than or equal to 50° and less than or equal to 65° relative to the {0001} plane. Therefore, the channel mobility at surface F1 can be increased as compared to the case where surface F1 corresponds to the {0001} plane. More preferably, the first or second condition set forth below is satisfied.

Under the first condition, the angle between the off orientation of surface F1 and the <1-100> direction of single crystal substrate 11 is less than or equal to 5°. Further preferably, the off angle of surface F1 relative to the {03-38} plane in the <1-100> direction of single crystal substrate 11 is greater than or equal to −3° and less than or equal to 5°.

Under the second condition, the angle between the off orientation of surface F1 and the <11-20> direction of single crystal substrate 11 is less than or equal to 5°.

As used herein, “the off angle of surface F1 relative to the {03-38} plane in the <1-100> direction” refers to the angle between the orthogonal projection of the normal line of surface F1 on the projecting plane defined by the <1-100> direction and <0001> direction and the normal line of the {03-38} plane. The sign is positive when the aforementioned orthogonal projection approaches the <1-100> direction in parallel, and negative when the aforementioned orthogonal projection approaches the <0001> direction in parallel.

Although the above description is based on the preferable orientation for surface F1 of single crystal substrate 11, preferably the same applies to the orientation for each surface of other single crystal substrates 12-19 (FIG. 1).

Although supporting portion 30 (FIG. 1) of a square shape is depicted, the shape of the supporting portion is not limited to a square, and may be a circle, for example. In this case, the diameter of the supporting portion is preferably greater than or equal to 5 cm, more preferably greater than or equal to 15 cm.

Although a resistance heating method using an electrical resistance heater for heater 50 is taken as an example, other heating methods can be employed. For example, the high-frequency induction heating or lamp annealing method may be employed.

In the present embodiment, a relative motion was carried out between a pad and main surface FO in one linear direction for the formation of irregularities. The direction of the relative motion may be in random. Accordingly, the direction of the irregularities will be random, allowing formation of irregularities with small anisotropy.

### Second Embodiment

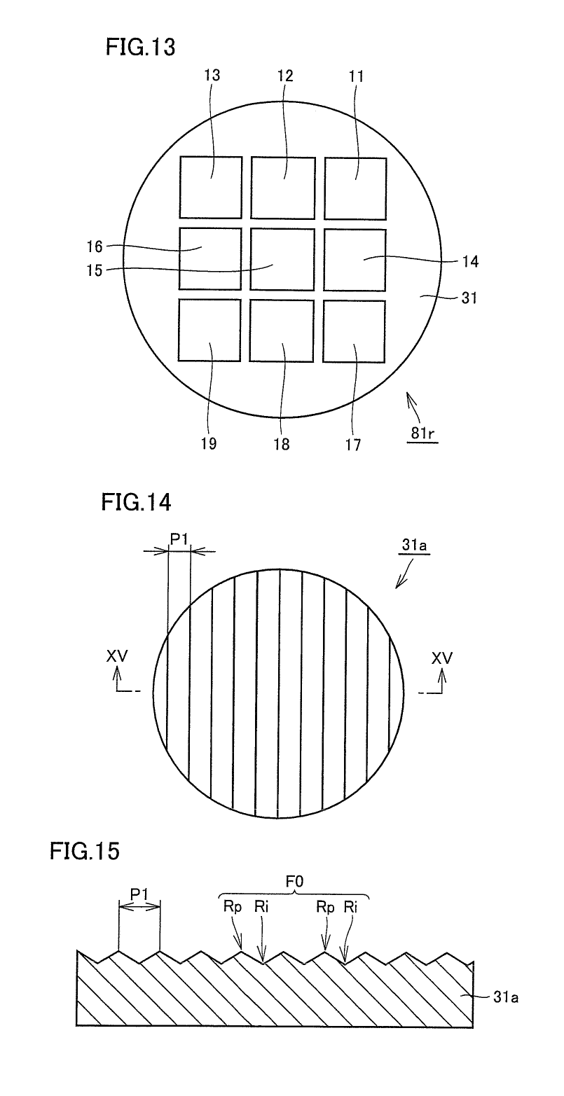

Referring to FIG. 13, a silicon carbide substrate 81r of the present embodiment is made of SiC, likewise with silicon carbide substrate 81 (FIG. 1: first embodiment). The plane shape of the silicon carbide substrate is a circle having a diameter of 10 cm, for example. Silicon carbide substrate 81r has a supporting portion 31 substantially similar to supporting portion 30 (FIG. 1: first embodiment). The configuration of other elements is substantially similar to that of the first embodiment set forth above. Therefore, the same or corresponding elements have the same reference characters allotted, and description thereof will not be repeated.

A method for manufacturing silicon carbide substrate 81r will be described hereinafter. First, a substrate substantially similar to substrate 30b (FIG. 3: first embodiment) is prepared.

Referring to FIGS. 14 and 15, a supporting portion 31a having irregularities on main surface FO is provided by forming irregularities at the main surface of the aforementioned substrate. The formation of irregularities is carried out so as to apply a predetermined surface feature at main surface FO. In other words, formation of irregularities is carried out to apply a surface feature corresponding to a designed pattern. To this end, the surface feature is applied by, for example, photolithography, press working, laser, ultrasonic machining, or the like. When photolithography is employed, etching is carried out using a photomask. The etching may be wet etching or dry etching.

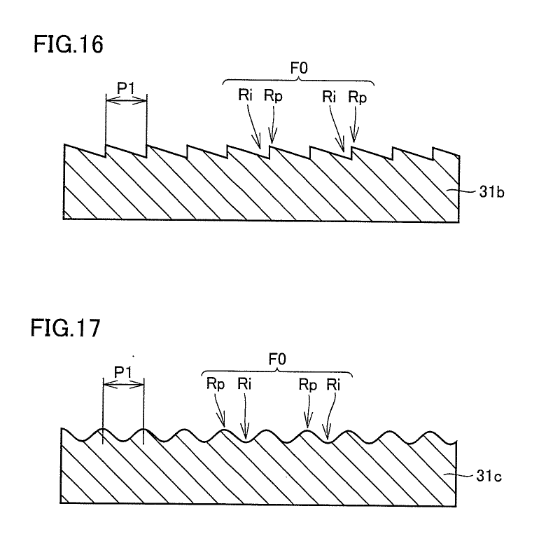

Supporting portion 31a includes a plurality of recesses Ri (FIG. 15) extending in a first direction (vertical direction in FIG. 14) on main surface FO, and a plurality of projections Rp (FIG. 15) extending in the same direction, and has a periodic structure of a period P1 in a direction orthogonal to the first direction (horizontal direction in FIGS. 14 and 15). The cross section of the surface feature by recess Ri and projection Rp is a triangle wave, as shown in FIG. 15. However, the cross section of the surface feature is not limited to a triangle wave. For example, a supporting portion 31b having a cross section of a sawtooth wave (FIG. 16), or a supporting portion 31c having a cross section of a sine wave (FIG. 17) may be employed.

Subsequently, steps similar to those set forth in the first embodiment are carried out, whereby silicon carbide substrate 81r (FIG. 13) is obtained.

The present embodiment provides advantages substantially similar to those of the first embodiment. Since a predetermined surface feature is applied to supporting portions 31a-31c, a more controllable cavity GQ (FIG. 9) can be provided, as compared to the case where a random surface feature is applied, as in the first embodiment. Therefore, the aforementioned advantage can be achieved more reliably.

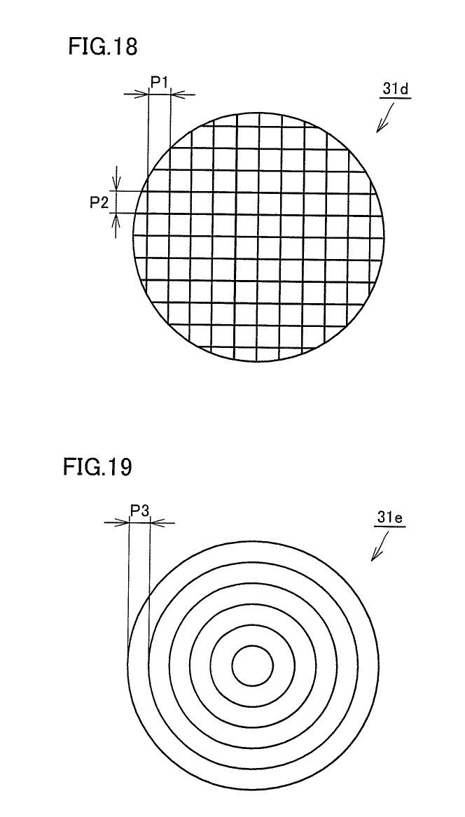

A modification of the present embodiment will be described with reference to FIG. 18. A supporting portion 31d prepared in the present modification includes a plurality of recesses extending in a second direction (horizontal direction in FIG. 18), in addition to recesses Ri (FIG. 15) extending in the first direction (vertical direction in FIG. 18) on the main surface. Regarding the periodic structure of the surface feature at supporting portion 31d, period P1 in the direction orthogonal to the first direction does not necessarily have to be identical to a period P2 in a direction orthogonal to the second direction. Preferably, the first and second directions are orthogonal to each other.

According to the present modification, cavity GQ (FIG. 9) is repeatedly formed, not only in the direction orthogonal to the first direction (direction of period P1), but also the direction orthogonal to the second direction (direction of period P2). Accordingly, cavity GQ can be distributed more evenly on supporting portion 31d, allowing further enhancement of the advantages of the present invention.

Another modification of the present embodiment will be described hereinafter with reference to FIG. 19. A supporting portion 31e prepared in the present modification includes a plurality of recesses Ri and a plurality of projections Rp in concentric arrangement. In other words, the surface feature of supporting portion 31d includes a plurality of recesses Ri extending in the circumferential direction. Supporting portion 31e may have a periodic structure of a period P3, radially.

The present modification is advantageous in that application of anisotropy corresponding to a specific linear direction to the silicon carbide substrate can be avoided since the surface feature is not formed in a specific linear direction.

### Third Embodiment

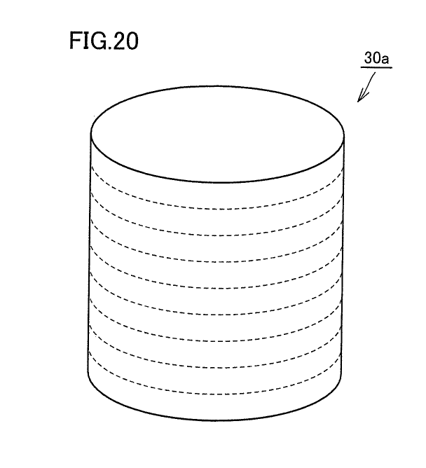

In a method for manufacturing a silicon carbide substrate according to the present embodiment with reference to FIG. 20, a mass 30a made of SiC is prepared. Mass 30a is, for example, an ingot of SiC single crystal. As indicated by the broken line in the drawing, mass 30a is sliced. This slicing is carried out by cutting with a wire saw, for example. By this slicing, supporting portion 30c (FIG. 5: first embodiment) is formed directly. Namely, a main surface FO having irregularities from the beginning is formed, instead of carrying out a step of forming irregularities on main surface FO. The surface roughness Ra of main surface FO formed by slicing is preferably less than or equal to 10 μm, more preferably less than or equal to 1 μm. The remaining steps are substantially similar to those of the first or second embodiment. Therefore, description thereof will not be repeated.

In the present embodiment, irregularities are formed on main surface FO in association with the formation of main surface FO (FIG. 5). Therefore, the steps for manufacturing a silicon carbide substrate 81 (FIG. 2) can be simplified since an independent step just for the formation of irregularities is not required.

### Fourth Embodiment

In the present embodiment, a structure corresponding to supporting portion 30c (FIG. 6: first embodiment) is formed by compacting SiC powder. In this case, random irregularities having a size corresponding to the grain size of the powder is formed at main surface FO of supporting portion 30c. The direction of irregularities is random. The powder is prepared such that the grain size is distributed substantially in the range of 10 μm to 50 μm, for example. The steps subsequent to the preparing step of supporting portion 30c are substantially similar to those of the first or second embodiment. Therefore, description thereof will not be repeated.

According to the present embodiment, supporting portion 30c can be prepared through an extremely simple method of compacting SiC powder. Therefore, the steps of manufacturing a silicon carbide substrate 81 (FIG. 2) can be simplified significantly.

### Fifth Embodiment

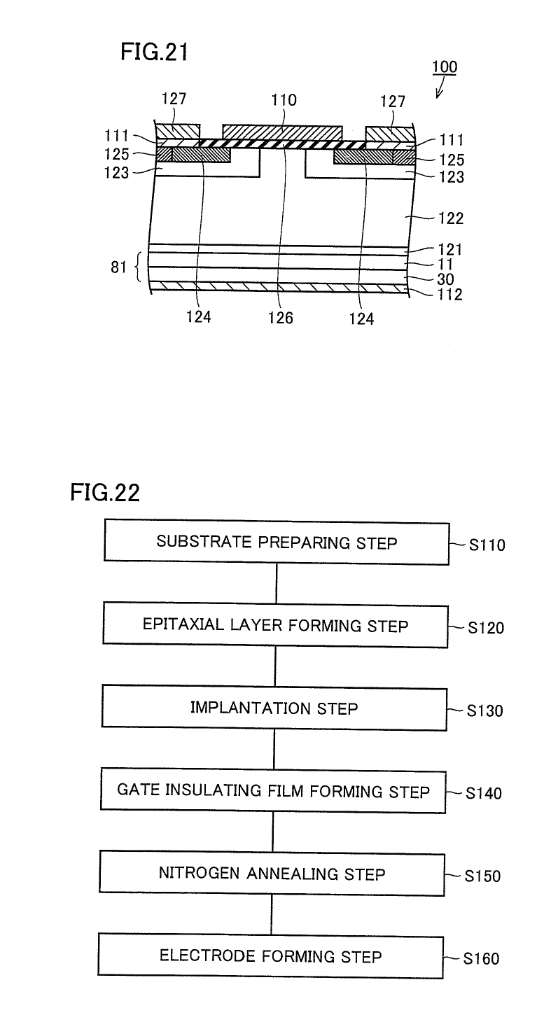

Referring to FIG. 21, a semiconductor device 100 of the present embodiment is a vertical type DiMOSFET (Double Implanted Metal Oxide Semiconductor Field Effect Transistor), including a silicon carbide substrate 81, a buffer layer 121, a breakdown voltage holding layer 122, a p region 123, an n⁺ region 124, a p⁺ region 125, an oxide film 126, a source electrode 111, an upper source electrode 127, a gate electrode 110, and a drain electrode 112.

Silicon carbide substrate 81 has an n type conductivity in the present embodiment, and includes supporting portion 30 and single crystal substrate 11, as described in the first embodiment. Drain electrode 112 is provided on supporting portion 30 such that supporting portion 30 is located between single crystal substrate 11 and drain electrode 112. Buffer layer 121 is provided on single crystal substrate 11 such that single crystal substrate 11 is located between supporting portion 30 and buffer layer 121.

Buffer layer 121 has an n type conductivity, and a thickness of 0.5 μm, for example. The concentration of the n type conductivity impurities in buffer layer 121 is 5×10¹⁷ cm⁻³, for example.

Breakdown voltage holding layer 122 is formed on buffer layer 121, and made of silicon carbide of n type conductivity. For example, breakdown voltage holding layer 122 has a thickness of 10 μm and an n type conductivity impurity concentration of 5×10¹⁵ cm⁻³.

At the surface of this breakdown voltage holding layer 122, a plurality of p regions 123 of p type conductivity are formed spaced apart from each other. In p region 123, n⁺ region 124 is formed at the surface layer of p region 123. At a region adjacent to this n⁺ region 124, p⁺ region 125 is formed. There is also an oxide film 126 formed extending from above n⁺ region 124 at one of p regions 123, over p region 123, a region of breakdown voltage holding layer 122 exposed between the two p regions 123, and the other p region 123, as far as above n⁺ region 124 at the relevant other p region 123. Gate electrode 110 is formed on oxide film 126. Source electrode 111 is formed on n⁺ region 124 and p⁺ region 125. Upper source electrode 127 is formed on source electrode 111.

The maximum value of the nitrogen atom concentration at the region within 10 nm from the boundary between oxide film 126 and the semiconductor layer, i.e. n⁺ region 124, p⁺ region 125, p region 123 and breakdown voltage holding layer 122, is greater than or equal to 1×10²¹ cm⁻³. Accordingly, the mobility at particularly the channel region under oxide film 126 (the portion of p region 123 in contact with oxide film 126, and located between n⁺ region 124 and breakdown voltage holding layer 122) can be improved.

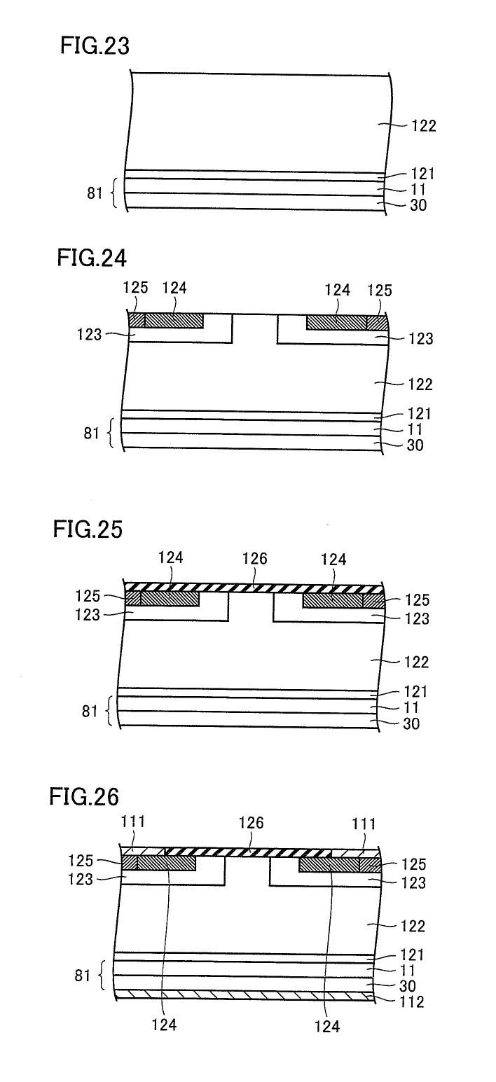

A method for manufacturing semiconductor device 100 will be described hereinafter. Although the steps in the proximity of single crystal substrate 11 among single crystal substrates 11-19 (FIG. 1) will be shown in FIGS. 23-26, similar steps are carried out in the proximity of each of single crystal substrate 12-single crystal substrate 19.

At a substrate preparing step (step S110: FIG. 22), silicon carbide substrate 81 (FIGS. 1 and 2) is prepared. The conductivity type of silicon carbide substrate 81 is the n type.

Referring to FIG. 23, by the epitaxial layer forming step (step S120: FIG. 22), buffer layer 121 and breakdown voltage holding layer 122 are formed as set forth below.

First, buffer layer 121 is formed on single crystal substrate 11 of silicon carbide substrate 81. Buffer layer 121 is made of silicon carbide of n type conductivity, and is an epitaxial layer having a thickness of 0.5 μm, for example. Further, the concentration of the conductivity type impurities in buffer layer 121 is 5×10¹⁷ cm⁻³, for example.

Then, breakdown voltage holding layer 122 is formed on buffer layer 121. Specifically, a layer of silicon carbide of n type conductivity is produced by epitaxial growth. Breakdown voltage holding layer 122 is set to have a thickness of 10 μm, for example. Further, the concentration of the n type conductivity impurities in breakdown voltage holding layer 122 is 5×10¹⁵ cm⁻³, for example.

Referring to FIG. 24, by an implantation step (step S130: FIG. 22), p region 123, n⁺ region 124, and p⁺ region 125 are formed as set forth below.

First, p type conductivity impurities are selectively implanted to a portion of breakdown voltage holding layer 122 to form p region 123. Then, n type conductivity impurities are selectively implanted into a predetermined region to form n⁺ region 124. By selectively implanting p type conductivity impurities into a predetermined region, p⁺ region 125 is formed. Selective implantation of impurities is conducted using a mask composed of an oxide film, for example.

Following the implantation step, an activation annealing process is carried out. For example, annealing is carried out for 30 minutes at the heating temperature of 1700° C. in an argon atmosphere.

Referring to FIG. 25, a gate insulating film forming step (step S140: FIG. 22) is carried out. Specifically, oxide film 126 is formed so as to cover breakdown voltage holding layer 122, p region 123, n⁺ region 124, and p⁺ region 125. This forming step may be carried out by dry oxidation (thermal oxidation). The conditions of dry oxidation include, for example, a heating temperature of 1200° C., and a heating duration of 30 minutes.

Then, a nitrogen annealing step (step S150) is carried out. Specifically, annealing is carried out in a nitric oxide (NO) atmosphere. The conditions of this process include, for example, a heating temperature of 1100° C., and a heating duration of 120 minutes. As a result, nitrogen atoms are introduced in the vicinity of the boundary between oxide film 126 and each of breakdown voltage holding layer 122, p region 123, n⁺ region 124 and p⁺ region 125.

Subsequent to this annealing step employing nitric oxide, an annealing process employing argon (Ar) gas identified as inert gas may be further carried out. The conditions of this process include, for example, a heating temperature of 1100° C. and a heating duration of 60 minutes.

Referring to FIG. 26, by an electrode forming step (step S160: FIG. 22), source electrode 111 and drain electrode 112 are formed as set forth below.

First, a resist film having a pattern is formed on oxide film 126 by photolithography. Using this resist film as a mask, the portion of oxide film 126 located above n⁺ region 124 and p⁺ region 125 is removed by etching. Accordingly, an opening is formed in oxide film 126. Then, a conductor film is formed to be brought into contact with each of n⁺ region 124 and p⁺ region 125 at this opening. By removing the resist film, the portion of the aforementioned conductor film located on the resist film is removed (lift off). This conductive film may be a metal film, made of nickel (Ni), for example. As a result of this lift off, source electrode 111 is formed.

At this stage, a heat treatment is preferably carried out for alloying. For example, a heat treatment is carried out for 2 minutes at the heating temperature of 950° C. in the atmosphere of argon (Ar) gas identified as inert gas.

Referring to FIG. 21 again, upper source electrode 127 is formed on source electrode 111. Also, drain electrode 112 is formed on the backside surface of silicon carbide substrate 81. Also, gate electrode 110 is formed on oxide film 126. Thus, a semiconductor device 100 is obtained.

A configuration in which the conductivity type is replaced in the present embodiment, i.e. a configuration in which the p type and n type are replaced, can be employed.

The silicon carbide substrate for producing semiconductor device 100 is not limited to silicon carbide substrate 81 of the first embodiment, and a silicon carbide substrate of any of the other embodiments may be employed.

Furthermore, although a vertical type DiMOSFET is taken as an example, another type of semiconductor device may be manufactured using the semiconductor substrate of the present invention. For example, a RESURF-JFET (Reduced Surface Field-Junction Field Effect Transistor), or a Schottky diode may be manufactured.

(Appendix 1)

The silicon carbide substrate of the present invention is produced by the manufacturing method summarized as below.

At least one single crystal substrate is prepared, each substrate having a backside surface and made of silicon carbide. A supporting portion having a main surface and made of silicon carbide is prepared. At least a portion of the main surface of the supporting portion has irregularities. The supporting portion and at least one single crystal substrate are stacked such that the backside surface of each at least one single crystal substrate and the main surface of the supporting portion having irregularities form contact each other. In order to connect the backside surface of each at least one single crystal substrate to the supporting portion, the supporting portion and at least one single crystal substrate are heated such that the temperature of the supporting portion exceeds the sublimation temperature of silicon carbide, and the temperature of each at least one single crystal substrate is below the temperature of the supporting portion.

(Appendix 2)

The semiconductor device of the present invention is produced using a semiconductor substrate produced by the manufacturing method summarized as below.

At least one single crystal substrate is prepared, each substrate having a backside surface and made of silicon carbide. A supporting portion having a main surface and made of silicon carbide is prepared. At least a portion of the main surface of the supporting portion has irregularities. The supporting portion and at least one single crystal substrate are stacked such that the backside surface of each at least one single crystal substrate and the main surface of the supporting portion having irregularities formed contact each other. In order to connect the backside surface of each at least one single crystal substrate to the supporting portion, the supporting portion and at least one single crystal substrate are heated such that the temperature of the supporting portion exceeds the sublimation temperature of silicon carbide, and the temperature of each at least one single crystal substrate is below the temperature of the supporting portion.

It should be understood that the embodiments disclosed herein are illustrative and non-restrictive in every respect. The scope of the present invention is defined by the scope of the claims, rather than the description set forth above, and is intended to include any modification within the scope and meaning equivalent to the terms of the claims.

### REFERENCE SIGNS LIST

11-19 single crystal substrate; 30, 30c, 31, 31a-31e supporting portion; 81, 81r silicon carbide substrate; 91 first heat body; 92 second heat body; 100 semiconductor device.

1. A method for manufacturing a silicon carbide substrate, comprising the steps of:
preparing a plurality of single crystal substrates, each having a backside surface and made of silicon carbide;
preparing a supporting portion having a main surface and made of silicon carbide, at least a portion of said main surface of said supporting portion having irregularities;
stacking said supporting portion and said plurality of single crystal substrates such that said backside surface of each of said plurality of single crystal substrates and said main surface of said supporting portion having said irregularities formed contact each other; and
heating said supporting portion and said plurality of single crystal substrates such that a temperature of said supporting portion exceeds a sublimation temperature of silicon carbide, and a temperature of each of said plurality of single crystal substrates is below a temperature of said supporting portion in order to connect said backside surface of each of said plurality of single crystal substrates to said supporting portion.

2. The method for manufacturing a silicon carbide substrate according to claim 1, wherein said step of preparing a supporting portion includes the step of forming said main surface, and the step of forming said irregularities on said main surface.

3. The method for manufacturing a silicon carbide substrate according to claim 2, wherein said step of forming said irregularities includes the step of grinding said main surface so as to roughen said main surface.

4. The method for manufacturing a silicon carbide substrate according to claim 3, wherein said step of grinding said main surface includes the step of grinding said main surface in one linear direction.

5. The method for manufacturing a silicon carbide substrate according to claim 2, wherein said step of forming said irregularities includes the step of applying a predetermined surface feature to said main surface.

6. The method for manufacturing a silicon carbide substrate according to claim 5, wherein said surface feature includes a plurality of recesses extending on said main surface along a first direction.

7. The method for manufacturing a silicon carbide substrate according to claim 6, wherein said surface feature includes a recess extending on said main surface along a second direction crossing said first direction.

8. The method for manufacturing a silicon carbide substrate according to claim 5, wherein said surface feature includes a recess extending on said main surface in a circumferential direction.

9. The method for manufacturing a silicon carbide substrate according to claim 1, wherein, in said step of preparing a supporting portion, a surface layer having a distortion in a crystal structure is formed on said main surface,
further comprising the step of chemically removing at least a portion of said surface layer before said step of stacking said supporting portion and said plurality of single crystal substrates.

10. The method for manufacturing a silicon carbide substrate according to claim 1, wherein said plurality of single crystal substrates have a hexagonal crystal structure, and an off angle greater than or equal to 50° and less than or equal to 65° relative to a {0001} plane.

11. The method for manufacturing a silicon carbide substrate according to claim 1, wherein said irregularities have a random direction.

12. The method for manufacturing a silicon carbide substrate according to claim 1, wherein said step of preparing a supporting portion includes the step of forming said main surface by slicing, said irregularities being formed by said slicing.

13. The method for manufacturing a silicon carbide substrate according to claim 1, wherein said backside surface of each of said plurality of single crystal substrates is formed by slicing.

14. The method for manufacturing a silicon carbide substrate according to claim 1, wherein said heating step is carried out in an atmosphere having pressure higher than 10⁻¹ Pa and lower than 10⁴ Pa.
